(19) United States
(12) Patent Application Publication
(10) Pub. No.: US 2024/0312783 A1
(43) Pub. Date: Sep. 19, 2024

(54) MASK ABSORBER LAYERS FOR EXTREME ULTRAVIOLET LITHOGRAPHY

(71) Applicant: The Regents of the University of California, Oakland, CA (US)

(72) Inventor: Daniel Staaks, Fremont, CA (US)

(21) Appl. No.: 18/357,297

(22) Filed: Jul. 24, 2023

Related U.S. Application Data
(63) Continuation of application No. PCT/US2022/013560, filed on Jan. 24, 2022.
(60) Provisional application No. 63/143,111, filed on Jan. 29, 2021.

(51) Int. Cl. H01L 21/027

(52) U.S. Cl. CPC H01L 21/027

(57) ABSTRACT

This disclosure provides systems, methods, and apparatus related to extreme ultraviolet lithography. In one aspect, a method of fabricating a mask for extreme ultraviolet lithography includes providing a structure, depositing an absorber layer over the reflective layer, and patterning the absorber layer. The structure includes a substrate and a reflective layer disposed over the substrate. The absorber layer comprises A and B. A is chromium (Cr) or vanadium (V). B is silver (Ag), indium (In), cobalt (Co), antimony (Sb), tin (Sn), or tellurium (Te). Patterning the absorber layer includes etching the absorber layer to remove the absorber layer in a first region while leaving the absorber layer in a second region. The etching is performed at a temperature of about −80° C. to 0° C.

### RELATED APPLICATIONS

This application claims priority to PCT Application No. PCT/US2022/013560, filed Jan. 24, 2022, which claims priority to U.S. Provisional Patent Application No. 63/143,111, filed Jan. 29, 2021, both of which are herein incorporated by reference.

### STATEMENT OF GOVERNMENT SUPPORT

This invention was made with government support under Contract No. DE-AC02-05CH11231 awarded by the U.S. Department of Energy. The government has certain rights in this invention.

### TECHNICAL FIELD

This disclosure relates generally to extreme ultraviolet (EUV) lithography and more specifically to masks for EUV lithography.

### BACKGROUND

The continuous decrease in critical feature sizes induces continuous advances in the semiconductor industry. Until now, projection lithography has been the workhorse technology for parallel, high-throughput patterning of large areas. In order to continue the use of projection lithography, smaller wavelengths are required. Extreme ultraviolet (EUV) lithography uses smaller wavelengths and is slated to be a major process technology for future semiconductor fabrication.

EUV lithography is different from conventional refractive optics in that it uses reflective optics. This is due to the strong absorption of materials at the short wavelength (13.5 nanometers (nm)) required. A EUV mask comprises a reflective multilayer mirror that is coated with a patterned mask absorber. The material of the mask absorber attenuates the EUV radiation, so that when the reflected EUV light hits the target wafer, the exposure mimics the pattern of the EUV mask.

The fabrication of the mask absorber is an important aspect of EUV lithography. There are two characteristics of such mask absorbers are needed. The first is that the mask absorber needs to be patterned with sufficient control over the cross-sectional shape. This also includes the patterning of features with improved critical dimensions for future devices. The second aspect is the material used needs to have a high extinction coefficient and a refractive index close to unity at the EUV wavelength (13.5 nm).

### SUMMARY

Described herein is a EUV mask and a method of making thereof. The EUV mask has an improved absorber layer. The absorber layer is an alloy or a compound of chromium or vanadium and at least one other metal. The other metal used in the alloy is a high extinction coefficient (k) material, such as silver (Ag), indium (In), cobalt (Co), antimony (Sb), tin (Sn), or tellurium (Te).

An advantage of the alloy is that it can be controllably patterned by plasma processing by using a self-passivation mechanism of chromium and vanadium. The sidewall passivation is available due to the ternary etch product formed in chromium or vanadium etching, which allows for re-deposition of selective intermediate products. This allows for direct anisotropic patterning or tapered sidewalls of features with dimensions currently not accessible. The new absorber layer alloy can be adjusted in extinction coefficient by stoichiometry and has higher extinction coefficient than current tantalum-based absorber materials. This allows for thinner absorber layers.

One innovative aspect of the subject matter described in this disclosure can be implemented in a method of fabricating a mask for lithography including providing a structure. The structure comprises a substrate and a reflective layer disposed over the substrate. An absorber layer is deposited over the reflective layer. The absorber layer comprises A and B. A is chromium (Cr) or vanadium (V). B is silver (Ag), indium (In), cobalt (Co), antimony (Sb), tin (Sn), or tellurium (Te). The absorber layer is patterned. The patterning includes etching the absorber layer to remove the absorber layer in a first region while leaving the absorber layer in a second region. The etching is performed at a temperature of about −80° C. to 0° C.

In some embodiments, the depositing is performed using magnetron sputtering or co-evaporation. In some embodiments, the etching is performed using reactive ion etching. In some embodiments, the etching is performed at a temperature of about −50° C. to −30° C. In some embodiments, the etching is performed using a gas mixture comprising oxygen and chlorine.

In some embodiments, the absorber layer comprises (1) chromium and antimony or (2) vanadium and antimony. In some embodiments, the absorber layer comprises about 30 to 93 atomic % A and about 7 to 70 atomic % B. In some embodiments, a thickness of the absorber layer is about 5 nanometers to 65 nanometers.

In some embodiments, the structure includes a capping layer disposed on the reflective layer, and the capping layer comprises ruthenium. In some embodiments, the reflective layer is reflective at a wavelength, and the absorber layer is absorbent at the wavelength. In some embodiments, the wavelength is about 9 nanometers to 18 nanometers.

In some embodiments, the reflective layer comprises alternating layers of molybdenum and silicon. In some embodiments, the structure includes an antireflective layer disposed on the reflective layer, and the antireflective layer comprises Si₃N₄, Si—C—N, or Si—C.

In some embodiments, patterning the absorber layer includes etching the absorber layer to form a trench in the absorber layer having a depth of about 5 nanometers to 65 nanometers and a width of about 5 nanometers to 1 millimeter. In some embodiments, the trench in the absorber layer has an aspect ratio (height/width) of about 0.0001 to 10.

Another innovative aspect of the subject matter described in this disclosure can be implemented in an extreme ultraviolet mask including a substrate, a reflective layer disposed over the substrate, and an absorber layer disposed over the reflective layer. The absorber layer comprises A and B. A is chromium (Cr) or vanadium (V). B is silver (Ag), indium (In), cobalt (Co), antimony (Sb), tin (Sn), or tellurium (Te).

In some embodiments, the absorber layer comprises (1) chromium and antimony or (2) vanadium and antimony. In some embodiments, the absorber layer comprises about 30 to 93 atomic % A and about 7 to 70 atomic % B. In some embodiments, a thickness of the absorber layer is about 5 nanometers to 65 nanometers.

In some embodiments, the absorber layer is patterned to define a trench having a depth of about 5 nanometers to 65 nanometers and a width of about 5 nanometers to 1 millimeter. In some embodiments, the trench in the absorber layer has an aspect ratio (height/width) of about 0.0001 to 10.

In some embodiments, the reflective layer includes a capping layer. The capping layer comprises ruthenium. The absorber layer is disposed on the capping layer.

In some embodiments, the reflective layer comprises alternating layers of silicon and molybdenum. In some embodiments, the reflective layer is reflective at a wavelength, and the absorber layer is absorbent at the wavelength. In some embodiments, the wavelength is about 9 nanometers to 18 nanometers.

In some embodiments, structure includes an antireflective layer disposed on the reflective layer, and the antireflective layer comprises Si₃N₄, Si—C—N, or Si—C.

Details of one or more embodiments of the subject matter described in this specification are set forth in the accompanying drawings and the description below. Other features, aspects, and advantages will become apparent from the description, the drawings, and the claims. Note that the relative dimensions of the following figures may not be drawn to scale.

### BRIEF DESCRIPTION OF THE DRAWINGS

FIG. 1 shows an example of a flow diagram illustrating a manufacturing process for a mask for extreme ultraviolet lithography.

FIG. 2 shows an example of an extreme ultraviolet mask.

FIG. 3 shows the increase in aspect ratio that occurs with smaller feature sizes.

FIG. 4A shows an example of a schematic illustration of anisotropically etched chromium with mask on top. FIG. 4B shows an example of a schematic illustration isotropically etched chromium with the mask being undercut.

FIG. 5A shows schematic illustrations of profile shapes observed for low-temperature chromium etching. The profile changes from left to right, from strongly bowed (I), to slightly bowed (IIa) or cavernously undercut (IIb), to anisotropic (III), and to over passivated or tapered (IV). These changes occur with an increase in DC bias voltage, an increase in oxygen/chlorine partial pressure ratio, or a decrease in trench width. The difference between a bowed profile (IIa) and a profile with bottom anisotropy and trench top cavernous undercut profile (IIb) is dependent on the oxygen partial pressure. The bowed profile (IIa) was found to occur at low O₂ concentrations, while the cavernous undercut profile (IIb) was found to occur at high oxygen concentrations. FIGS. 5B and 5C the show etch windows found for profile shapes presented in FIG. 5A, with DC bias voltage as a function of O₂ concentration. Between process windows, transition regions exist. For example, the anisotropic etch window, area (III), changes with DC bias voltage and oxygen concentration. Outside of the etch window towards the lower left of O₂% and DC bias voltage, the profile starts lateral etching (II) & (I). Increasing O₂% and DC bias voltage beyond the anisotropic etch window over passivation can be observed as profile (IV). Chromium sidewall profiles are also dependent on the trench width. FIG. 5B shows the results for a 40 nanometers (nm) trench width. FIG. 5C shows the results for areas of same profile for a feature edge towards open area (i.e., infinite trench width). Note that at low oxygen concentration and high DC bias voltages the Cr/hydrogen silsesquioxane (HSQ) resist selectivity was insufficient to obtain same the etch depth as for the other profiles.

FIGS. 6A-6F show example of micrographs of trenches all etched in the anisotropic etch regime at 25% oxygen concentration and −50° C. FIG. 6A shows a micrograph of a mask before etching. The mask has a 72° to 78° taper. FIG. 6B shows a micrograph of trenches etched with 190 V DC bias voltage (35 W RF Power) with +13% over etch. Note that sidewall bowing was reduced due to increased passivant deposition compared to a 172 V DC bias voltage in FIG. 6F. Aspect ratio for a 15 nm trench: 3.25. FIG. 6C shows a micrograph of a tilted view of a vertical pattern edge towards open area to show surface of the sidewall. Etching was performed at 190 V DC bias voltage. FIG. 6D shows a micrograph of isolated lines etched at 190 V DC bias voltage. FIG. 6E shows a micrograph of the smallest feature achieved at 190 V DC bias voltage, with a 5 nm opening and a 9 nm trench width. FIG. 6F shows a micrograph of features etched at 172 V DC bias voltage with various over etch percentages with respect to the time required to completely etch away the chromium. Note that even at 41% over etch, lateral erosion was relatively small at the open area. The aspect ratio at 13% over etch, 20 nm trench width was 2.9. A conductive polymer and metal (CPM) coating was used for the micrographs shown in FIGS. 6A, 6B and 6D-6F.

FIG. 7 shows an example of a graph of extinction coefficient as a function of energy in eV. At 12.5 nm (99.2 cV), 13.5 nm (91.8 cV), and 14.5 nm (85.5 eV), CrSb has a higher absorption coefficient compared to chromium.

FIG. 8 shows an example of a graph of extinction coefficient as a function of refractive index for CrSb and other materials, such as Ta, TaBN, V, and Sb.

FIGS. 9A-9C show examples of micrographs of two trenches, one 27 nm wide and one 155 nm wide, for different etching conditions. FIG. 9A: −50° C. and 5W RF power. FIG. 9B: −50° C. and 15W RF power. FIG. 9C: −30° C. and 15W RF power.

FIG. 10A-10C shows examples of micrographs of feature size changes with mask opening. FIG. 10B shows a micrograph magnified to image the smallest dimensions. FIG. 10C shows a micrograph of a 5 nm trench with a 40 nm etch depth.

FIG. 11 shows an example of a micrograph of a smooth sidewall of a feature edge.

### DETAILED DESCRIPTION

Reference will now be made in detail to some specific examples of the invention including the best modes contemplated by the inventors for carrying out the invention. Examples of these specific embodiments are illustrated in the accompanying drawings. While the invention is described in conjunction with these specific embodiments, it will be understood that it is not intended to limit the invention to the described embodiments. On the contrary, it is intended to cover alternatives, modifications, and equivalents as may be included within the spirit and scope of the invention as defined by the appended claims.

In the following description, numerous specific details are set forth in order to provide a thorough understanding of the present invention. Particular example embodiments of the present invention may be implemented without some or all of these specific details. In other instances, well known process operations have not been described in detail in order not to unnecessarily obscure the present invention.

Various techniques and mechanisms of the present invention will sometimes be described in singular form for clarity. However, it should be noted that some embodiments include multiple iterations of a technique or multiple instantiations of a mechanism unless noted otherwise.

The terms “about” or “approximate” and the like are synonymous and are used to indicate that the value modified by the term has an understood range associated with it, where the range can be ±20%, ±15%, ±10%, ±5%, or ±1%. The terms “substantially” and the like are used to indicate that a value is close to a targeted value, where close can mean, for example, the value is within 80% of the targeted value, within 85% of the targeted value, within 90% of the targeted value, within 95% of the targeted value, or within 99% of the targeted value.

Described herein are (1) extreme ultraviolet (EUV) masks having an absorber layer of a new material and (2) methods of making thereof. Improvements in the methods of fabrication are based on findings and improvements in the patterning of the metal chromium. Chromium has been investigated in the past for EUV masks, but was discontinued due to issues with patterning the chromium with sufficient control over the final cross-sectional shape of the etched features. Achievable chromium feature aspect ratios were limited to <1, which also results in limitations regarding the minimum feature sizes obtainable.

The etch mechanism of re-deposition has been discussed in the scientific literature for silicon and gallium arsenide etching. A self-passivation mechanism, which included re-deposition, was found to be a dominant process in low temperature reactive ion etching of chromium with oxygen and chlorine. Re-deposition occurs when etching chromium with oxygen and chlorine because chromium forms only one ternary volatile compound (CrO₂Cl₂) with these gasses. Vanadium also potentially exhibits a similar behavior.

Chromium and vanadium, however, have a lower extinction coefficient at 13.5 nanometers (nm) than tantalum-based mask absorbers. TaBN is currently the absorber material of choice. To increase the extinction coefficient of chromium and vanadium, chromium and vanadium alloys can be used. For example, chromium or vanadium in combination with high extinction coefficient materials such silver (Ag), indium (In), cobalt (Co), antimony (Sb), tin (Sn), or tellurium (Te) can be used.

Creating materials such alloys or compounds (e.g., CrₓSb_{y}, CrₓSn_{y}, Cr—Co) would combine the advantages of a high extinction coefficient material with the advantages of the chromium etch process. Depending on the stoichiometry, the compound would have higher extinction coefficient than chromium or vanadium alone, while also potentially being able to etch under self-passivation.

In plasma based dry etching (e.g., reactive ion etching), materials are etched by a chemical reaction. If the etching reaction forms a volatile product, the product can be removed from the surface of the material (i.e., the product would be removed when the material being etched is under vacuum). Volatile products are generally formed with halogens, oxygen, or hydrogen. Thus, reactive gasses used in etching processes that generate volatile products include fluorine, chlorine, bromine, oxygen, or hydrogen.

It was expected and confirmed that chromium or vanadium alloys also form volatile products. For example, CrSb etched in a chlorine/oxygen plasma would form products including CrO₂Cl₂. SbCl₃ and SbCl₅. Thus, when etching CrSb with oxygen and chlorine, the passivation mechanism would be present as well.

Also described herein are EUV mask absorbers including a chromium (Cr) or vanadium (V) based alloy or compound. A second element of the alloy or compound is silver (Ag), indium (In), cobalt (Co), tin (Sn), antimony (Sb), or tellurium (Te). These alloys have high extinction coefficient at EUV wavelength. Some current absorber layers include tantalum-based compounds (e.g., often TaBN), which have extinction coefficients close to that of chromium. A chromium-based alloy of compounds with Ag, In, Co, Sn, Sb, or Te will provide the benefits of improved extinction coefficient while also being able to improve patterning using a self-passivation mechanism.

Advantages of the embodiments described herein include:
Using chromium or vanadium alloys or compounds as a EUV absorber layer would increase the extinction coefficient of the absorber material. This means that the absorber layer can be thinner while maintaining the same level of EUV radiation attenuation. Further, the extinction coefficient can be changed by changing the alloy composition.
Thinner EUV absorber layers can be fabricated more easily with improved critical dimensions. In addition, it would diminish 3D mask effects, which are an issue in EUV lithography.
The improvements in patterning in the chromium etch process would allow for precise feature profile control. Full anisotropy and tapered sidewalls are possible.
The fabrication processes allow for an aspect ratio greater than 1 due to the self-passivation mechanism.
The fabrication processes allow for direct patterning of chromium or vanadium alloys or compounds with anisotropic or tapered profiles, without lateral etching. This direct anisotropy allows for a preservation of mask dimensions. This enables the etching of smaller features, and also enables higher aspect ratios.
Sidewall angles from 90 degrees to tapered can be achieved.

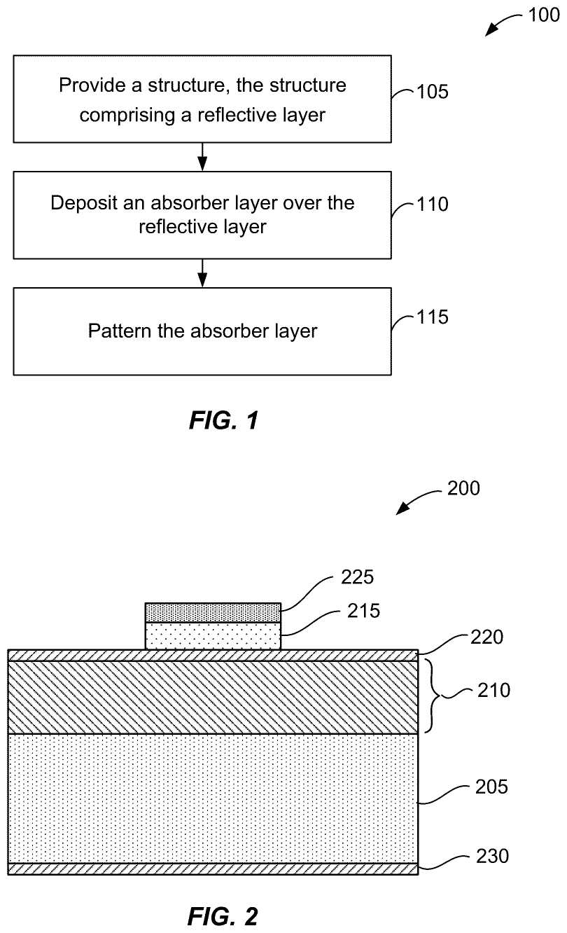

FIG. 1 shows an example of a flow diagram illustrating a manufacturing process for a mask for extreme ultraviolet lithography. Starting at block 105 of the process 100, a structure is provided. The structure comprises a substrate and a reflective layer disposed over the substrate.

In some embodiments, the reflective layer includes first reflective layers and second reflective layers which are alternately stacked. In some embodiments, the reflective layer includes a periodic multilayer including first reflective layers and second reflective layers. In some embodiments, the first reflective layers comprise molybdenum and the second reflective layers comprise silicon. In some embodiments, the first reflective layers comprise silver and the second reflective layers comprise ruthenium. In some embodiments, the reflective layer comprises alternating layers of molybdenum and silicon. In some embodiments, a layer of a third material is disposed between the first reflective layers and the second reflective layers. In some embodiments, the third material comprises carbon.

In some embodiments, the structure includes an antireflective layer disposed on the reflective layer. In some embodiments, the antireflective layer comprises Si₃N₄, Si—C—N, or Si—C. In some embodiments, the structure includes a capping layer disposed on the reflective layer or on the antireflective layer (if the structure includes an antireflective layer). In some embodiments, the capping layer comprises ruthenium.

Returning to FIG. 1, at block 110, an absorber layer is deposited over the reflective layer. The absorber comprises or consists essentially of A and B. A is chromium (Cr) or vanadium (V). B is silver (Ag), indium (In), cobalt (Co), antimony (Sb), tin (Sn), or tellurium (Te). In some embodiments, the absorber layer is deposited on the reflective layer. In some embodiments, the reflective layer is deposited on the capping layer. In some embodiments, the absorber layer is deposited using magnetron sputtering or co-evaporation. In some embodiments, the absorber layer is about 5 nm to 65 nm thick.

In some embodiments, absorber layer comprises about 30 to 93 atomic % A and about 7 to 70 atomic % B. In some embodiments, the absorber layer comprises about 90 atomic % A and about 10 atomic % B.

In some embodiments, the absorber layer comprises or consists essentially of (1) chromium and antimony or (2) vanadium and antimony. Different phases of chromium and antimony (e.g., CrSb and CrSb₂) and vanadium and antimony (e.g., VSb and VSb₂) exist.

In some embodiments, the reflective layer is reflective at a wavelength, and the absorber layer is absorbent at the wavelength. In some embodiments, the wavelength is about 9 nm to 18 nm. In some embodiments, the wavelength is about 13.5 nm.

Returning to FIG. 1, at block 115, the absorber layer is patterned. As will be understood by one having skill in the art, the terms “patterning” and “patterned” are used to refer to masking as well as etching processes. The patterning includes etching the absorber layer to remove the absorber layer in a first region while leaving the absorber layer in a second region. The etching is performed at a temperature of about −80° C. to 0° C. In some embodiments, the etching is performed at a temperature of about −50° C. to −30° C.

In some embodiments, the etching is performed using reactive ion etching. Reactive ion etching is a type of dry etching that uses a chemically reactive plasma to remove material. In some embodiments, the plasma is a microwave electron cyclotron resonance plasma, an inductively coupled plasma, a capacitively coupled plasma, or combinations thereof. In some embodiments, the etching is performed using a gas mixture comprising oxygen and chlorine to form the plasma. In some embodiments, the gas mixture comprises about 1% to 80% partial pressure oxygen and 20% to 99% partial pressure chlorine. In some embodiments, the gas mixture includes an inert gas (e.g., argon or helium).

In some embodiments, etching is performed at a total gas pressure of about 5 mTorr. Etching for high aspect ratios and small features is typically performed at low pressures. Standard ICP etchers do not typically work well at pressures below about 2 mTorr. The pressure in an ICP etcher should not exceed about 50 mTorr. There are high-density plasma reactors that operate at pressures lower than 2 mTorr. For example, the operating pressures for some electron cyclotron resonance plasma etching apparatus is about 0.005 mTorr to 10 mTorr. In some embodiments, the DC bias voltage during ICP etching is about 1 V to 350 V.

In some embodiments, patterning the absorber layer includes etching the absorber layer to form a trench in the absorber layer having a depth of about 5 nm to 65 nm and a width of about 5 nm to 1 millimeter (mm). For example, the trench may be a tapered trench that is 25 nm deep and 5 nm wide at the bottom of the trench. In some embodiments, patterning the absorber layer includes removing the absorber layer from a region to expose the underlying reflective layer (or the capping layer). The process 100 shown in FIG. 1 can also be used to etch a feature edge (e.g., an edge with no opposing trench wall). In some embodiments, the trench in the absorber layer has an aspect ratio (height/width) of about 0.0001 to 10.

In some embodiments, after block 110 and prior to block 115, an antireflective layer is deposited on the absorber layer. Then, in block 115, both the antireflective layer and the absorber layer are etched. In some embodiments, the antireflective layer is deposited using evaporation (e.g., e-beam evaporation or thermal evaporation) or sputter coating. In some embodiments, the antireflective layer comprises Si₃N₄, Si—C—N, or Si—C.

FIG. 2 shows an example of an extreme ultraviolet mask. The mask 200 shown in FIG. 2 includes a substrate 205, a reflective layer 210 disposed over the substrate 205, and an absorber layer 215 disposed over the reflective layer 210. As seen in FIG. 2, the absorber layer 215 is patterned. The absorber layer comprises or consists essentially of A and B. A is chromium (Cr) or vanadium (V). B is silver (Ag), indium (In), cobalt (Co), antimony (Sb), tin (Sn), or tellurium (Te).

In some embodiments, the reflective layer is reflective at a wavelength, and the absorber layer is absorbent at the wavelength. In some embodiments, the wavelength is about 9 nm to 18 nm. In some embodiments, the wavelength is about 13.5 nm.

In some embodiments, the substrate 205 comprises a low-thermal expansion material. In some embodiments, the substrate 205 includes a conductive backside coating 230 disposed on the side on which the reflective layer 210 is not disposed.

In some embodiments, the reflective layer 210 includes first reflective layers and second reflective layers which are alternately stacked. In some embodiments, the reflective layer 210 includes a periodic multilayer including first reflective layers and second reflective layers. In some embodiments, the first reflective layers comprise molybdenum and the second reflective layers comprise silicon. In some embodiments, the first reflective layers comprise silver and the second reflective layers comprise ruthenium. In some embodiments, the reflective layer 210 comprises alternating layers of molybdenum and silicon. In some embodiments, a layer of a third material is disposed between the first reflective layers and the second reflective layers. In some embodiments, the third material comprises carbon.

In some embodiments, an antireflective layer (not shown) is disposed on the reflective layer 210. In some embodiments, the antireflective layer comprises Si₃N₄, Si—C—N, or Si—C. In some embodiments, a capping layer 220 is disposed on the reflective layer 210 or on the antireflective layer (if an antireflective layer is disposed on the reflective layer 210). In some embodiments, the capping layer 220 comprises ruthenium.

In some embodiments, an antireflective layer 225 is disposed on the absorber layer 215. In some embodiments, the antireflective layer 225 comprises Si₃N₄, Si—C—N, or Si—C. In some embodiments, the antireflective layer 225 is patterned when the absorber layer 215 is patterned.

In some embodiments, the absorber layer 215 is deposited on the reflective layer 210. In some embodiments, the absorber layer 215 is deposited on the capping layer 220. In some embodiments, the absorber layer 210 is about 5 nm to 65 nm thick.

In some embodiments, absorber layer 215 comprises about 30 to 93 atomic % A and about 7 to 70 atomic % B. In some embodiments, the absorber layer 215 comprises about 90 atomic % A and about 10 atomic % B.

In some embodiments, the absorber layer 215 comprises or consists essentially of (1) chromium and antimony or (2) vanadium and antimony. Different phases of chromium and antimony (e.g., CrSb and CrSb₂) and vanadium and antimony (e.g., VSb and VSb₂) exist.

In some embodiments, a trench having a depth of about 5 nm to 65 nm and a width of about 5 nm to 1 mm is patterned in the absorber layer 215. For example, the trench may be a tapered trench that is 25 nm deep and 5 nm wide at the bottom of the trench. In some embodiments, the trench in the absorber layer 215 has an aspect ratio (height/width) of about 0.0001 to 10.

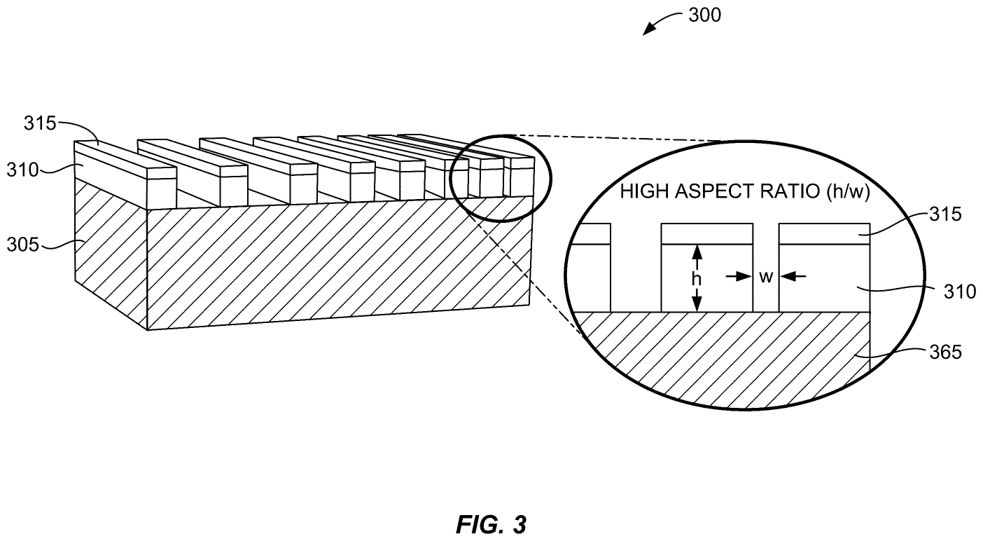

FIG. 3 shows the increase in aspect ratio that occurs with smaller feature sizes. The mask 300 shown in FIG. 3 includes a substrate 305, an absorber layer 310 disposed over the substrate 305, and a resist material 315 disposed over the absorber layer. The resist material 315 is removed from the mask 300 after the fabrication process. Not shown in FIG. 3 is the reflective layer. For the absorber layer 310, a decrease in feature sizes increases the aspect ratio (aspect ratio (AR)=height (h)/width (w)) of an etched trench in the absorber layer 310.

### EXAMPLES

The examples below include specific implementations of the embodiments described herein, and are not intended to be limiting. Studies on chromium as a material for nanofabrication have been performed. Recent results demonstrate the etch properties of chromium when using a new low-temperature based fabrication method.

### Example—Chromium Etching

Chromium is an important material in micro- and nanofabrication due to its many beneficial material properties, such as electrical conductivity, wear resistance, high optical density, and ultra-thin oxide formation. Out of these properties a variety of applications arise, which can be roughly divided into two main categories: (1) chromium can be used as a hard mask to an underlying material and act as chemically and physically highly selective masking material to oxides, nitrides, carbides, and other materials; and (2) chromium can be used as the actual functional material. For example, chromium has been used as an optical absorber in quantum tunneling devices and for transistor fabrication, as well as mechanical applications. For both uses, the chromium is patterned using plasma based dry etching methods using chlorine/oxygen chemistry, where a volatile ternary product CrO₂Cl₂ forms.

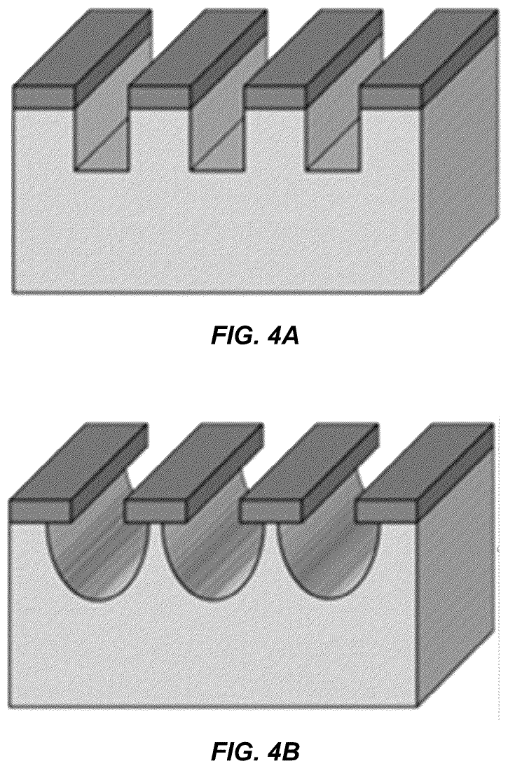

While inductively coupled plasma (ICP) etching is a method to achieve high performance etch results on large areas with small feature dimensions, improvements in the chromium dry-etch process have always been challenging. In particular, the etch reaction is primarily chemical in nature, which makes it difficult to achieve vertical features and maintaining dimensions. FIGS. 4A and 4B show the difference between isotropically and anisotropically etched chromium.

When chromium is etched using a resist mask, the lateral etch rate limits the obtainable trench aspect ratio of the chromium to <1.2 and affects critical dimensions. Moreover, etch rate variations between large and small features, dense and sparsely patterned areas, and over the whole wafer due to the global loading effect have led mask makers to alter lithographic mask dimensions to accommodate undesired feature size changes during chromium etching. However, for future device fabrication with tight process margins and future single-digit nanometer features, etch profile control will be needed.

As a work around, for more than 40 years these challenges in chromium etching were gradually mitigated by decreasing the chromium thickness, adding other elements to chromium, using oxide or nitride hard masks instead of carbon based resists, or investigating and changing the etch parameters. Literature reports on current state-of-the-art chromium patterning show the tradeoffs for small feature sizes due to the limits of achievable aspect ratios. For example, feature sizes of 19 nm were shown with a spin-on glass resist for an 11 nm chromium thickness (aspect ratio of 0.6). Regarding bulk chromium films for photomask fabrication, the smallest reported feature sizes are 50 nm on about 55 nm Cr layers (aspect ratio of 1.1).

In order to overcome the limitations and improve chromium etch performance, substrate temperature control was recently investigated as a means to improve the chromium etching process. Starting on blanket films, these studies showed that low temperature provides a variable for controlling etching rates. This is important for control of critical dimensions during nanoscale feature etching. In addition, it was found that the etching mechanisms could be changed with temperature and chlorine to oxygen ratios.

Starting from these observations, how these various etching mechanisms translated to anisotropic patterning was investigated. Features in sub-20 nm chromium films were patterned at etching temperatures of +20° C. and −50° C. using low RF power in ICP etching. It was found that specific chlorine to oxygen ratios (e.g., about 50%) combined with low temperature and low forward power improved anisotropic patterning. Process windows and mechanisms were explored and anisotropy was improved during the initial parts of the etching process, but the end of the etching process was difficult to control for 10 nm films. It was surmised that the source of the anisotropy was a passivation layer that formed with re-deposition of etch species from the trench bottom. This promoted good anisotropy until nearing the bottom of the feature. Anisotropic patterning of 15 nm feature sizes down to 10 nm depth was achieved. To improve anisotropy towards higher aspect ratios as well as bulk chromium, it was recognized that more studies were necessary.

Bulk chromium etching in a chlorine/oxygen gas chemistry was studied using ICP dry etching at −50° C. In particular, the patterning of chromium layers of about 100 nm thickness was studied using a hydrogen silsesquioxane (HSQ) resist. A HSQ resist provides high-resolution etching and a highly selective mask for chromium patterning. The O₂ partial pressure, RF forward power (resulting in a DC Bias), and feature dimensions were varied, showing that highly anisotropic dry etching of chromium can be achieved even in thick films all the way to the trench bottom.

As a result, full chromium etch profile control was demonstrated using low temperature ICP dry etching. The smallest features achieved were about 6.3 nm and aspect ratios of anisotropically etched features reached about 3.25, which is the current state-of-the-art.

### Example—Profile Control Using the Chromium Self-Passivation Mechanism

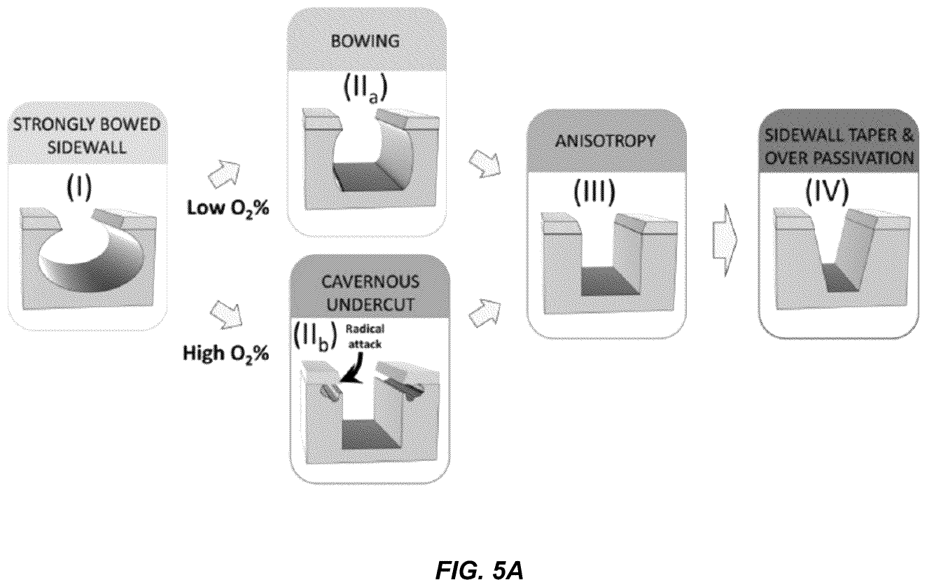

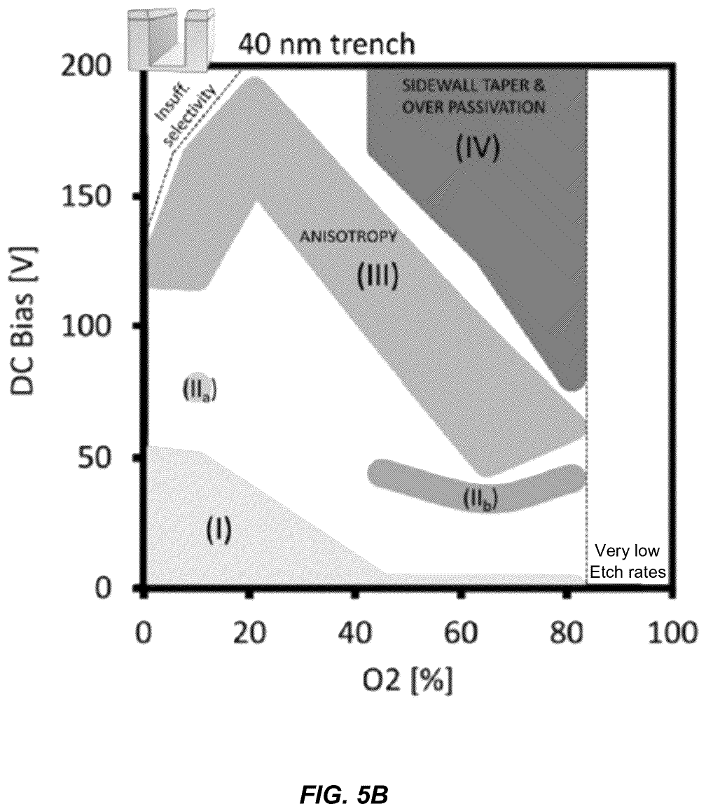

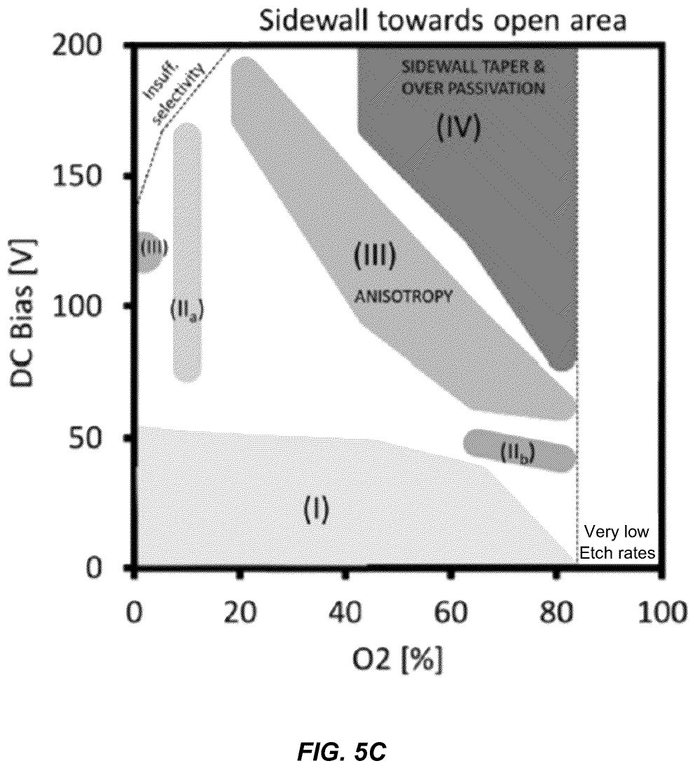

FIG. 5A schematically shows the general evolution of the patterned chromium profiles observed in a large variety of pattern profiles etched under various conditions of DC bias voltage, O₂ concentrations, and trench widths. Cross-sectional profiles formed using 1.6% to 81% oxygen changed from laterally etched and bowl shaped (I) to over passivated and tapered (IV), while transitioning through a region of full anisotropy (III).

These transitions occur from region (I) to region (IV), depending on the starting conditions, when the DC bias voltage was increased, the O₂ concentration was increased, or the trench width was decreased. In particular, it was found that the transition profile from a bowl shape (I) towards anisotropy (III) is dependent on the oxygen concentration. At oxygen concentrations ≥41%, the etch profile showed rectangular trench bottoms, while the top experienced a cavernous undercut, likely caused by a trench depth causing insufficient sidewall passivation at the top of the trench. The occurrence of cavernous undercut was likely not caused by off-axis ion scattering from trench edges. On the other hand, when oxygen concentrations were ≤25%, the sidewall top was protected, while the sidewall in its entirety started to widen by bowing.

By plotting data points of same profile shape in a plot of DC bias voltage against oxygen concentration, FIGS. 5B and 5C show the distribution of process windows for each shape. White areas represent transition regions. The dependency of trench width (aspect ratio) was addressed by plotting results for both a 40 nm trench and a sidewall towards open area.

Looking at the 40 nm trenches in FIG. 5B, it is seen that the shape of the anisotropic etch window (III) over oxygen concentration coincides with the changes of the chromium etch rate at low temperature. Between 10% and 81% oxygen partial pressure, profile anisotropy was maintained for increasing 02% by decreasing the DC bias voltage. Beyond this regime, moving towards higher 02% or higher DC bias voltage changed the profile to over passivated and tapered (IV). Moving towards lower 02% or lower DC bias voltage changed the profile to the lateral etch regime. At 1.6% of oxygen partial pressure, anisotropy was achieved at lower DC bias voltage compared to 10%. This change is consistent with the change in etch rates found for chromium, where the maximum etch rate at −50° C. was at 10% oxygen concentration.

In addition, the width of the process window narrows with high oxygen concentrations. For example, 81% oxygen partial pressure and 5 W RF power led to undercut, while 10 W was already over passivated. This indicates that long etch times lead to strong lateral inhibitor removal. This can be compensated for by strong passivation, which causes the regime of anisotropy to be only very narrow.

It is suspected that this difference in the profile transition with increasing oxygen concentration is caused by a change in the ratio between the rate of volatile product formation and the rate at which the inhibitor is deposited on the sidewalls. As both the inhibitor (i.e., chromium oxide or chromium chloride) and the volatile product (i.e., CrO₂Cl₂) are created from the same source, the trench bottom, it is assumed that both mechanisms are in competition with each other at the trench bottom during low temperature chromium etching.

At low oxygen concentration of 1.6%, there was also an anisotropy regime present at 120 V DC bias voltage, for both the 40 nm trench (FIG. 5B) and open area (FIG. 5C). However, for the open area shown in FIG. 5C, it was found that at 10% oxygen, anisotropy was not achieved for previously anisotropic regions in FIG. 5B. This is likely due to insufficient inhibitor formation, which needs more DC bias voltage to compensate for and thus the peak of the anisotropy regime. Note that due to insufficient selectivity between Cr and HSQ, it was not possible to establish tests with sufficient etch depth for low oxygen concentrations and high DC bias voltage voltages, as marked in FIGS. 5B and 5C.

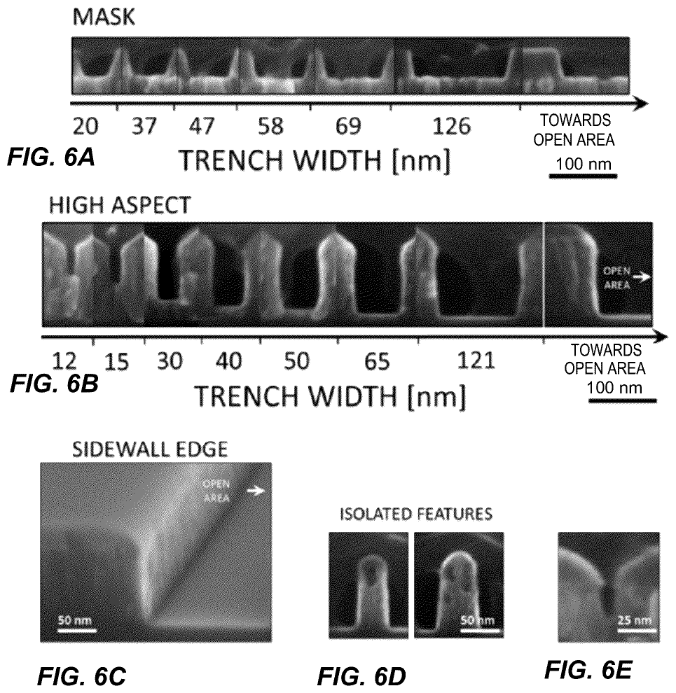

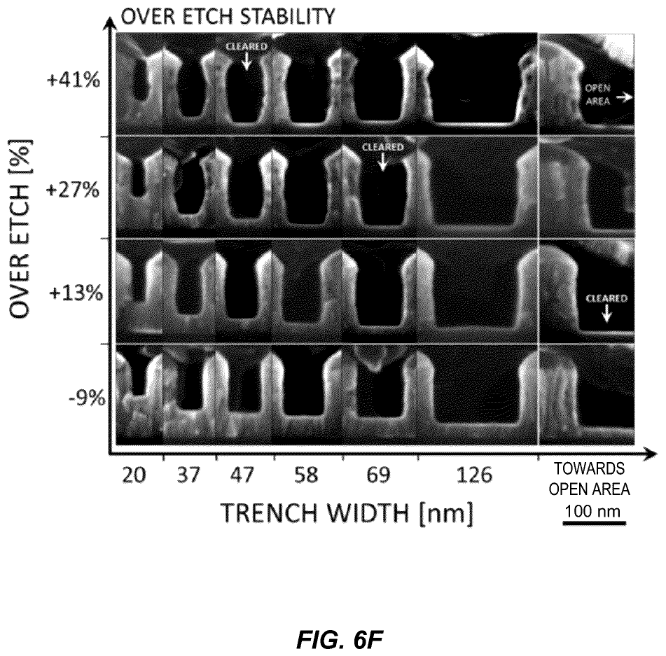

FIGS. 6A-6F show examples of results of samples etched in regime III in FIGS. 5A-5C with 111 nm chromium thickness, etched at 21% oxygen concentration, demonstrating the progress in etch profile control using the low-temperature chromium etch process. Before etching, the shape of the 46 nm thick HSQ mask is shown in FIG. 6A for different trench widths, which shows a faceted sidewall angle between 72 degrees and 78 degrees.

Etched chromium is shown in FIG. 6B-6F. The best results for this study are shown in FIG. 6B for 190 V DC bias voltage, all on the same sample. A trench width of 12 nm was etched anisotropically, while the trench bottom was reached for 65 nm trench width. The best aspect ratio obtained was 3.25. An etch lag towards smaller trench sizes can clearly be seen, where etching is aspect ratio limited, which is consistent to the well-known aspect ratio dependency in silicon and GaAs.

FIG. 6C shows a feature edge towards open area, at an angle and without a conductive polymer and metal (CPM) coating, in order to see the sidewall surface. It can be seen that the sidewall is flat with no significant roughness. A sidewall texturing seems to coincide with grain boundaries that appear very shallow, compared to grain diameters observed of up to 25 nm. This indicates that etching at sufficiently passivating conditions prevents grain boundary preferential etching.

To show results of purely isolated features, FIG. 6D shows isolated features with 40 nm and 66 nm width at the base of the feature. It can be assumed that with improved better adjusted e-beam dose for isolated features, or with improved Cr/Mask selectivity and <111 nm chromium thickness, much thinner lines could be created as well. The smallest trench width was a 5 nm opening with a 9 nm etched trench width, shown in FIG. 6E.

FIG. 6F shows samples etched in regime III in FIGS. 5A-5C, etched at 196 V DC bias voltage (32.5 W RF) with varying over etch percentages at −9% to +41%, showing the stability of the protective sidewall etch inhibitor layer. Over etch was defined as the time the open area chromium was removed. Different trenches are shown between 20 nm wide and trench edges towards open area. It can be seen that when chromium was still at the bottom (−9%), the trenches were etched without undercut and with straight sidewalls. At 13% over etch, anisotropy was maintained—the sidewall was still sufficiently protected and did not suffer from undercut. Smaller trenches were etched deeper, but at the expense of a sidewall bowing effect. With increasing etch time to 27% over etch, this effect became more apparent, but sidewall integrity was maintained. At 41% over etch time, the sidewall started to show signs of local erosion, as seen for the largest trenches, presumably as the sidewall protection started to break down.

These results show that the sidewall passivant is stable even past clearing the chromium in open areas. The smallest trench width where chromium was removed at the bottom was 47 nm. When using a thinner masking material, smaller trenches could be obtained. For the smallest trenches of 20 nm, the change in etch time also reveals a dependency of the etch profile on etch time and a limitation on achievable aspect ratio. The profile deepened from −9% to +13%, resulting in an aspect ratio of 3. However, increasing the etch time further did start to bow the sidewalls. This indicates that the achievable etch depth are aspect ratio limited, which causes the ratio of vertical to lateral etch rate to decrease.

It is suspected that the etch process is limited by neutral flux. Neutrals typically have strongly isotropic trajectories within the plasma sheath, which causes them to arrive at a broad range of incident angles. Therefore, their flux towards the trench bottom is strongly dependent on the aspect ratio of the feature. As the trench bottom is critical to providing both passivant and volatile product in the low temperature chromium etch process, the etch depth will be aspect ratio limited.

In conclusion, it was found that the chromium etch mechanism is based on the formation of an oxygen rich or chlorine rich intermediate etching product, which can redeposit on the sidewall and act as a passivant. By adjusting etch parameters, the formation of this passivant can be adjusted.

### Example—CrSb Extinction Coefficient

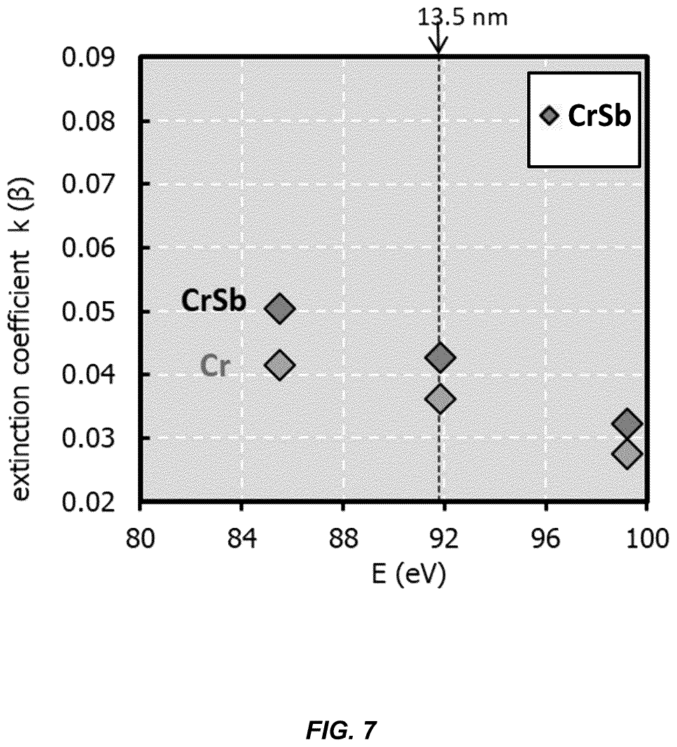

In order to quantitatively determine the difference in absorption of CrSb films, chromium and CrSb films were prepared for reflectance measurements. The absorption of CrSb and the absorption of chromium at the three different energies are shown in FIG. 7. The CrSb alloy with 10 at. % Sb content showed higher absorption compared pure chromium for all three energies.

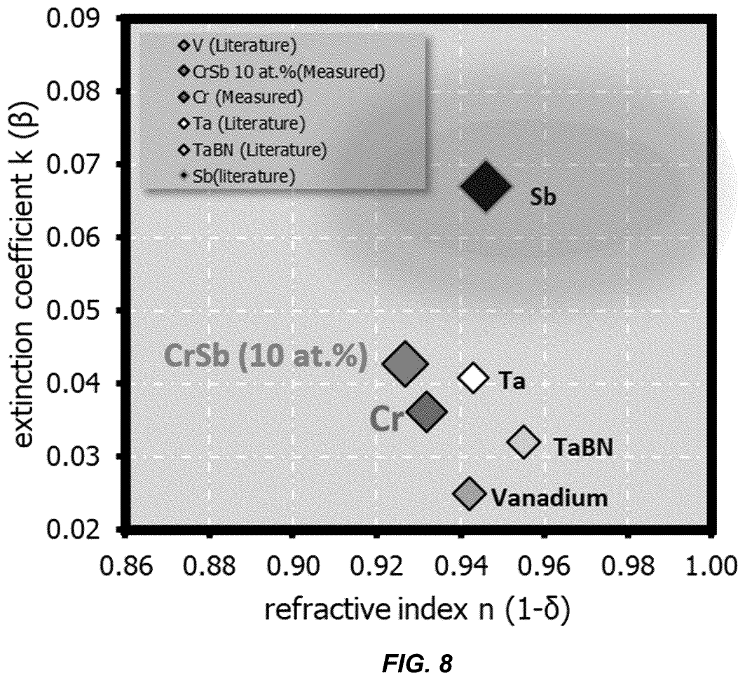

FIG. 8 shows the absorption at 13.5 nm for a number of materials. Comparing CrSb to other materials such as Sb, Ta, Cr, TaBN, and V, it can be seen the extinction coefficient of the new compound is between pure chromium and pure antimony, as expected. Further, CrSb shows better absorption than common tantalum-based EUV absorber materials (e.g., TaBN).

### Example—CrSb Etching

Experiments were performed to determine if CrSb films could be controllably etched using inductively coupled plasma reactive ion etching (ICP-RIE), similar to chromium.

The following procedure was used:
Deposition—Silicon wafer substrates (prime 4″ wafers) were cleaned using 15 min UV ozone cleaning. Deposition of 150 nm CrSb with 10 at. % antimony was performed using sputter deposition. The target thickness was 150 nm in order to have sufficient thickness available for high-aspect-ratio etching tests.
Mask patterning—A mask was fabricated by spin coating hydrogen silsesquioxane (HSQ) e-beam resist onto the wafers with a thickness of 60 nm. HSQ is highly selective in chromium etching and allows for high resolution pattering. Using e-beam lithography a cleavable line pattern was written and then developed using NaOH developer. The final thickness of the mask was 45 nm.
Dicing—Samples were then cleaved into 9 chips with 25 mm×25 mm.
Dry Etching—Etching was done using inductively coupled dry etching. The ICP power was held constant at 500 W. Temperature, O₂/Cl₂ feed gas concentration, RF forward power, and time were varied.
Cleaving—Samples were then cleaved along the pattern using a micrometer cleaving station.
Imaging—Imaging was done using a scanning electron microscope

Etching rates of CrSb were found to be lower than etching rates for chromium under the same conditions:

| | | | Etching Rate | Etch Rate |
|---|---|---|---|---|
| T | O₂ % | RF [W] | chromium | CrSb (10 at. %) |
| −50° C. | 12.5% | 15 | Ca. 10 nm/min | 1.92 nm/min |
| −50° C. | 50% | 15 | Ca. 7.5 nm/min | 2.25 nm/min |

Etching rates of CrSb were found to increase with increasing temperature:

| T | O₂ % | RF [W] | Etch Rate CrSb (10 at. %) |
|---|---|---|---|
| −50° C. | 12.5% | 15 | 1.92 nm/min |
| −30° C. | 12.5% | 15 | 4.79 nm/min |

CrSb does not etch when only chlorine is used in the feed gas. This is comparable to chromium etching, where etching rates are sensitive to the oxygen concentration in the chlorine/oxygen gas chemistry. Without oxygen, chromium also does not etch beyond the physical sputtering rate.

Etching profiles were found to be dependent on oxygen concentration, RF power, and temperature. This is comparable to chromium, where the same dependencies exist. Further, no undercut was detected

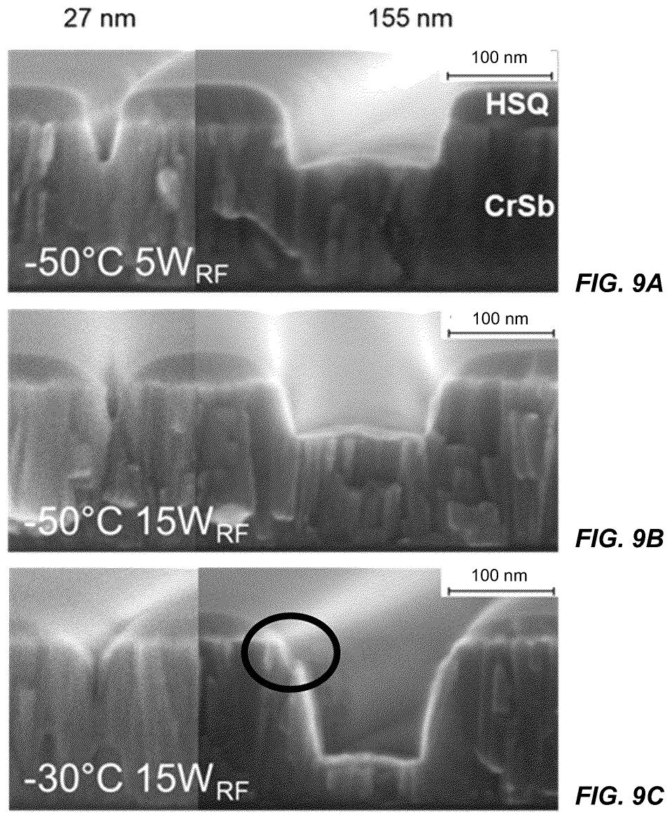

Sidewall erosion is visible near the top of the trench (FIG. 9C) at an elevated temperature of −30° C. Specifically, erosion (circle in FIG. 9C) is visible in features with wide trenches (small aspect ratio) but not visible in small trenches (high aspect ratio). As this behavior is seen in chromium (but to a much greater extent), the result indicates that sidewall passivation is also caused by inhibitor re-deposition. It appears that the antimony content in the compound protects the sidewall from being etched spontaneously, which is preferable for controlled dry etching.

The etching rates dropped with increasing RF power (FIGS. 9A and 9B). This phenomenon is seen in low-temperature chromium etching where smaller trenches with high aspect ratio reduce access of radicals from the plasma to the trench bottom. Similar to chromium etching, it can be assumed that strong competition between the formation of the volatile product and the etch inhibitor occurs on the trench bottom. The increase in RF power increases inhibitor sputtering from the trench bottom, which in turn causes a reduction in volatile product formation and therefore etching rates.

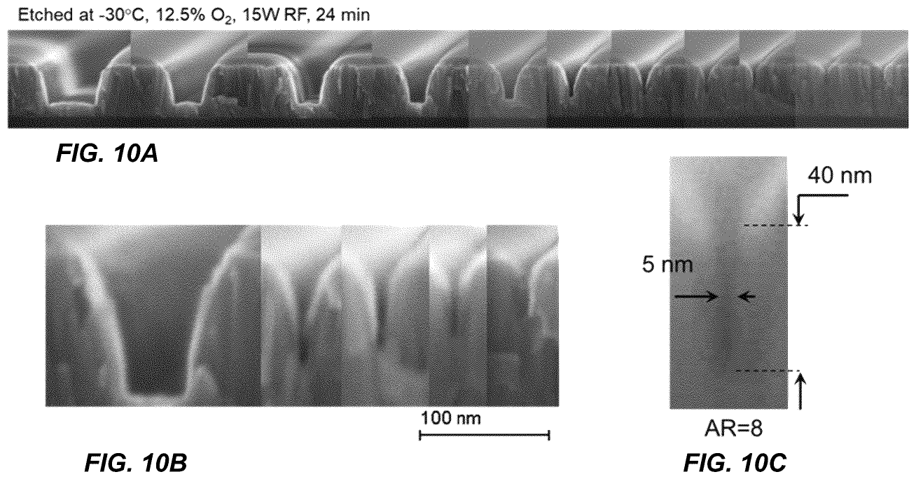

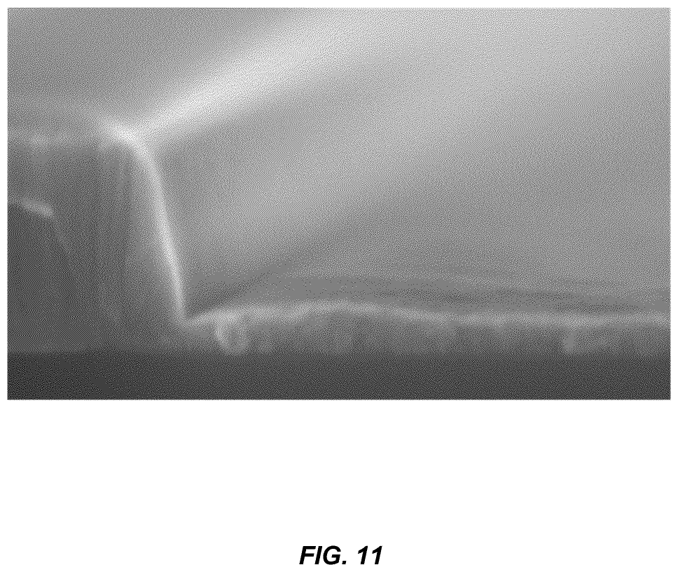

Minimum feature sizes of 5 nm were achieved with anisotropic etching down to 40 nm deep, which corresponds to an aspect ratio of 8 (FIGS. 10A-10C). These results exceed any result achieved with chromium etching, where a maximum aspect ratio of 3.25 was achieved for 9 nm trench width. Sidewalls of etched CrSb were found to be smooth, which is important for EUV mask fabrication (FIG. 11).

The work described in this example investigated how a material compound made from chromium and a high k material would perform at 13.5 nm wavelength. It was found that a compound made from chromium and antimony presents a good choice for high absorption and good etching properties. CrSb thin films can be prepared using magnetron sputtering with a single hot-pressed Cr/Sb target. Using reflectance measurements at 12.5 nm, 13.5 nm, and 14.5 nm, CrSb films with 10% antimony showed higher extinction coefficients at all wavelength compared to pure chromium. CrSb can be dry etched well in chlorine/oxygen gas chemistry. Temperature, oxygen concentration, RF power, and aspect ratio influence the etch profile, similar to the low temperature etching of chromium. Etch rates of CrSb are lower compared to chromium, which further improves etch profile control. At the extremes, etching CrSb features with 5 nm trench width and an aspect ratio of 8 exceed the possibilities of pure chromium etching. This work shows that CrSb has the properties needed to be used as EUV absorber material. Having excellent dry etching properties, CrSb fulfills the needs for sub-17 nm next-generation EUV mask fabrication.

### CONCLUSION

In the foregoing specification, the invention has been described with reference to specific embodiments. However, one of ordinary skill in the art appreciates that various modifications and changes can be made without departing from the scope of the invention as set forth in the claims below. Accordingly, the specification and figures are to be regarded in an illustrative rather than a restrictive sense, and all such modifications are intended to be included within the scope of invention.

What is claimed is:

1. A method of fabricating a mask for lithography, comprising:
providing a structure, the structure comprising:
a substrate, and
a reflective layer disposed over the substrate;
depositing an absorber layer over the reflective layer, the absorber layer comprising A and B, wherein A is chromium (Cr) or vanadium (V), and wherein B is silver (Ag), indium (In), cobalt (Co), antimony (Sb), tin (Sn), or tellurium (Te); and
patterning the absorber layer, the patterning including etching the absorber layer to remove the absorber layer in a first region while leaving the absorber layer in a second region, the etching being performed at a temperature of about −80° C. to 0° C.

2. The method of claim 1, wherein the depositing is performed using magnetron sputtering or co-evaporation.

3. The method of claim 1, wherein the etching is performed using reactive ion etching.

4. The method of claim 1, wherein the etching is performed at a temperature of about −50° C. to −30° C.

5. The method of claim 1, wherein the etching is performed using a gas mixture comprising oxygen and chlorine.

6. The method of claim 1, wherein the absorber layer comprises (1) chromium and antimony or (2) vanadium and antimony.

7. The method of claim 1, wherein the absorber layer comprises about 30 to 93 atomic % A and about 7 to 70 atomic % B.

8. The method of claim 1, wherein a thickness of the absorber layer is about 5 nanometers to 65 nanometers.

9. The method of claim 1, wherein the structure includes a capping layer disposed on the reflective layer, and wherein the capping layer comprises ruthenium.

10. The method of claim 1, wherein the reflective layer is reflective at a wavelength, and wherein the absorber layer is absorbent at the wavelength.

11. The method of claim 10, wherein the wavelength is about 9 nanometers to 18 nanometers.

12. The method of claim 1, wherein the reflective layer comprises alternating layers of molybdenum and silicon.

13. The method of claim 1, wherein the structure includes an antireflective layer disposed on the reflective layer, and wherein the antireflective layer comprises Si₃N₄, Si—C—N, or Si—C.

14. The method of claim 1, wherein patterning the absorber layer includes etching the absorber layer to form a trench in the absorber layer having a depth of about 5 nanometers to 65 nanometers and a width of about 5 nanometers to 1 millimeter.

15. The method of claim 1, wherein the trench in the absorber layer has an aspect ratio (height/width) of about 0.0001 to 10.

16. An extreme ultraviolet mask comprising:
a substrate;
a reflective layer disposed over the substrate; and
an absorber layer disposed over the reflective layer, the absorber layer comprising A and B, wherein A is chromium (Cr) or vanadium (V), and wherein B is silver (Ag), indium (In), cobalt (Co), antimony (Sb), tin (Sn), or tellurium (Te).

17. The extreme ultraviolet mask of claim 16, wherein the absorber layer comprises about 30 to 93 atomic % A and about 7 to 70 atomic % B.

18. The extreme ultraviolet mask of claim 16, wherein the absorber layer is patterned to define a trench having a depth of about 5 nanometers to 65 nanometers and a width of about 5 nanometers to 1 millimeter.

19. The extreme ultraviolet mask of claim 18, wherein the trench in the absorber layer has an aspect ratio (height/width) of about 0.0001 to 10.

20. The extreme ultraviolet mask of claim 16, wherein the structure includes an antireflective layer disposed on the reflective layer, and wherein the antireflective layer comprises Si₃N₄, Si—C—N, or Si—C.
